(19) United States
(12) Patent Application Publication
(10) Pub. No.: US 2022/0359220 A1
(43) Pub. Date: Nov. 10, 2022

(54) Etching Composition for Silicon Nitride Layer and Etching Method Using the Same

(71) Applicant: Industry-Academic Cooperation Foundation, Yonsei University, Seoul (KR)

(72) Inventors: Sang Woo Lim, Seoul (KR); Taegun Park, Gwacheon-si (KR)

(21) Appl. No.: 17/843,077

(22) Filed: Jun. 17, 2022

(30) Foreign Application Priority Data
May 4, 2021 (KR) 10-2021-0057589
Aug. 5, 2021 (KR) 10-2021-0102971

(51) Int. Cl. H01L 21/311; H01L 21/02

(52) U.S. Cl. CPC H01L 21/31116; H01L 21/0217

(57) ABSTRACT

Provided are an etching composition for a silicon nitride layer and an etching method using the same. An etching composition under pressure which selectively etches silicon nitride layers and suppresses etching of silicon oxide layers in a vertical stack structure the silicon nitride layers and the silicon oxide layers alternately deposited are exposed to the surface, and an etching method using the same, are provided.

### CROSS-REFERENCE TO RELATED APPLICATIONS

This application claims priority to Korean Patent Application Nos. 10-2021-0057589 filed May 4, 2021 and 10-2021-0102971 filed Aug. 5, 2021, the disclosures of which are hereby incorporated by reference in their entirety.

### BACKGROUND OF THE INVENTION

### Field of the Invention

The following disclosure relates to an etching composition for a silicon nitride and an etching method using the same. More particularly, the present disclosure relates to an etching composition which suppresses etching of a silicon oxide layer and selectively etches a silicon nitride layer in a vertical stack structure in which both the silicon nitride layer and the silicon oxide layer are exposed to surface, and an etching method using the same.

### Description of Related Art

A silicon oxide layer (SiOₓ) and a silicon nitride layer (SiNₓ) are used as a representative insulation film in a semiconductor manufacturing process, and are used alone, respectively, so that both of these layers are exposed to surface. Recently, in the manufacture of a memory semiconductor having a 3D vertical NAND (V-NAND) structure, a structure in which a silicon nitride layer and a silicon oxide layer are alternately deposited, as shown in FIG. 1, is used. Thus, an etching composition which may implement effective etchability even in a multilayered vertical stack structure as such, and a process of etching are demanded.

A conventional selective etching process of a silicon nitride layer uses an 85% phosphoric acid at a high temperature. Here, according to the Le Chatelier's principle, a loading effect in which an etching rate is lowered depending on the time and the number of processes occurs. Therefore, the replacement cycle of an etching composition is shortened, a consumption of a chemical is increased, and an increase in process costs therefrom is problematic. Besides, thinning of a silicon oxide layer of a semiconductor structure in a highly concentrated phosphoric acid occurs during an etching process of a silicon nitride layer, which may deteriorate the electrical properties of a semiconductor device.

In order to solve those problems, development of an etching composition to which an additive is added is needed. As an embodiment of the etching composition as such, Patent Document 1 discloses a non-phosphoric acid-based etching composition for a silicon nitride layer including an inorganic-based fluorine compound, a silicon-based compound, a polar organic solvent, and water. However, it is difficult to apply the composition to the manufacturing of V-NAND structure, since an etching rate of silicon nitride is as low as 32.5 Å/min on a blanket wafer and silicon oxide layer is very likely to redeposit on the pattern structure from the etch by-products and the silicon-based compound. In addition, Patent Document 2 discloses an etching composition to remove silicon nitride layers by adding modified silica or modified silicic acid into the mixture of phosphoric acid and water. However, the silicon oxide (SiOₓ) is very likely to redeposit due to the presence of silica or silicic acid in the phosphoric acid solution. Therefore, the composition is not appropriate as an etchant of silicon nitride layers in a V-NAND structure.

Thus, an etching composition and a related process to solve the problems in using phosphoric acid solution should be developed.

### Related Art Documents

### Patent Documents

(Patent Document 1) KR 10-2017-0030774 A

(Patent Document 2) KR 10-1769349 B1

### SUMMARY OF THE INVENTION

An embodiment of the present disclosure is directed to providing an etching composition under pressure which improves an etching rate of a silicon nitride layer as compared with a conventional etching process using an 85 wt % phosphoric acid, and may selectively etch silicon nitride layers against silicon oxide layers when silicon oxide and silicon nitride layers are exposed to the etchant. In particular, an etching composition which may exhibit effective etch performance even in a V-NAND structure is to be provided.

Specifically, the present disclosure provides an etching composition under pressure to selectively remove silicon nitride layers, not only for the structure in which both a silicon nitride layer and a silicon oxide layer are exposed to the surface, but also for a vertical stack structure in which the silicon nitride layers and the silicon oxide layers alternately deposited are exposed to the surface.

Another embodiment of the present disclosure is directed to providing a method of selective etching for a silicon nitride layer and a method of manufacturing a semiconductor device, using the etching composition under pressure described above.

In one general aspect, an etching composition under pressure, which is for the selective etching of a silicon nitride layer to a silicon oxide layer, includes: 85 wt % or less of a phosphoric acid, based on a total weight of the etching composition.

The etching composition according to an exemplary embodiment of the present disclosure may be used at 2 to 20 atm.

The etching composition according to an exemplary embodiment of the present disclosure may satisfy the following (A) to (C):

(A) an etching rate of the silicon nitride layer is 50 Å/min or more,

(B) an etching rate of the silicon oxide layer is 0 to 10 Å/min, and

(C) an etching selectivity of the silicon nitride layer to the silicon oxide layer, which is defined as a ratio of an etching rate of a silicon nitride layer to an etching rate of a silicon oxide layer, is 2 to 400.

Furthermore, the etching composition according to an exemplary embodiment may satisfy the following (D) as well as (A) to (C):

(D) in a vertical stack structure having the silicon oxide layer and the silicon nitride layer as a unit layer, an outer thickness (Tₒ) to an inner thickness (Tᵢ) of the silicon oxide layer satisfies the following Equation 1:

0.90≤Tₒ/Tᵢ≤1.0 [Equation 1]

The etching composition according to an exemplary embodiment of the present disclosure may include 30 to 70 wt % of the phosphoric acid.

When the etching composition according to an exemplary embodiment of the present disclosure includes 30 to 70 wt % of the phosphoric acid, an etching selectivity obtained from the etching composition may be 10 to 400.

The etching composition according to an exemplary embodiment of the present disclosure may not include the compound containing a silicon atom.

In another general aspect, an etching method includes: selective etching of a silicon nitride layer to a silicon oxide layer through pressurization, using the etching composition described above.

In the etching method according to an exemplary embodiment of the present disclosure, an object to be etched of the etching composition may be a wafer in which both the silicon oxide layer and the silicon nitride layer are exposed to the surface; or a wafer having stack structures having the silicon oxide layer and the silicon nitride layer as a unit layer.

In the etching method according to an exemplary embodiment of the present disclosure, the pressurized conditions may be in a range of 2 to 20 atm.

The etching method according to an exemplary embodiment of the present disclosure may be for etching at a high temperature of 100° C. or higher.

In still another general aspect, a method of manufacturing a semiconductor device using the etching composition is provided.

Other features and aspects will be apparent from the following detailed description, the drawings, and the claims.

### BRIEF DESCRIPTION OF THE DRAWINGS

FIG. 1 is an exemplary drawing of a vertical stack structure of a silicon nitride layer and a silicon oxide layer.

FIG. 2 shows an etching example (Example 4) in the vertical stack structure according to the present disclosure.

FIG. 3 shows an etching example (Example 5) in the vertical stack structure according to the present disclosure.

FIG. 4 shows an etching example (Example 6) in the vertical stack structure according to the present disclosure.

FIG. 5 shows an etching example (Comparative Example 1) in the vertical stack structure according to the present disclosure.

FIG. 6 shows a method of determining an etching rate and an etching selectivity in the vertical stack structure according to the present disclosure.

### DESCRIPTION OF THE INVENTION

Hereinafter, the present disclosure will be described in detail. Technical terms and scientific terms used in the present specification have the general meaning understood by those skilled in the art to which the present disclosure pertains unless otherwise defined, and a description for the known function and configuration obscuring the present disclosure will be omitted in the following description.

In addition, the singular form used in the present specification may be intended to also include a plural form, unless otherwise indicated in the context.

In addition, units used in the present specification without particular mention are based on weights, and as an example, a unit of % or ratio refers to a wt % or a weight ratio and wt % refers to wt % of any one component in a total composition, unless otherwise defined.

In addition, the numerical range used in the present specification includes all values within the range including the lower limit and the upper limit, increments logically derived in a form and span in a defined range, all double limited values, and all possible combinations of the upper limit and the lower limit in the numerical range defined in different forms. As an example, when it is defined that a numerical value is 100 to 10,000, specifically 500 to 5,000, it should be interpreted as being that a numerical range of 500 to 10,000 or 100 to 5,000 is also described in the specification of the present disclosure. Unless otherwise defined in the specification of the present disclosure, values which may be outside a numerical range due to experimental error or rounding of a value are also included in the defined numerical range.

The term “comprise” in the present specification is an open-ended description having a meaning equivalent to the term such as “is/are provided”, “contain”, “have”, or “is/are characterized”, and does not exclude elements, materials, or processes which are not further listed.

The term “substantially consisting of . . . ” in the present specification means that other elements, materials, or processes which are not listed together with specified elements, materials, or processes may be present in an amount which does not have an unacceptable significant influence on at least one basic and novel technical idea of the disclosure. In addition, it means that an influence therefrom is insignificant.

The term “etching selectivity (E_{SiNx}/E_{SiO2})” in the present specification refers to a ratio of an etching rate of a silicon nitride layer (E_{SiNx}) to an etching rate of a silicon oxide layer (E_{SiO2}). Therefore, when the etching rate of a silicon oxide layer is close to zero or the numerical value of the etching selectivity is high, it is regarded that a silicon nitride layer is selectively etched.

A conventional selective etching of a silicon nitride layer has been performed using a phosphoric acid at a high temperature. However, etching rate of a silicon oxide layer further increases at a higher temperature, it is difficult to obtain a high etching selectivity of a silicon nitride layer to a silicon oxide layer. Besides, in a 3D V-NAND structure, silicon oxide layers are thinned during the etching process. As a method for solving the problem, recently, etching compositions with an additive which is a compound containing a silicon atom having various structures have been suggested. However, although these etching compositions may increase an etching selectivity, regrowth of an oxide around a silicon oxide layer which is expected to be caused by an additive became an issue in manufacturing 3D NAND devices.

Meanwhile, since an etching rate to an object to be etched is generally proportional to the concentration of an etchant, an etchant composition including a less concentrated phosphoric acid may have a decreased etching rate as compared with the etchant composition including a highly concentrated phosphoric acid. However, an etching reaction of a silicon nitride layer by a phosphoric acid is as shown in the following Reaction Formula 1. It was confirmed from the present inventor's research that an etching rate is not simply proportional only to the concentration of the phosphoric acid, but is determined by a product of the concentration of the phosphoric acid and the concentration of water.

3Si₃N₄+27H₂O+4H₃PO₄→4 (NH₄)₃PO₄+9H₂SiO₃ [Reaction Formula 1]

In the recognition as such, the present inventors confirmed that there are the conditions of the etching composition including a less concentrated phosphoric acid which may provide a similar etching rate to the case of including 85 wt % of the phosphoric acid. However, because the boiling point of the less concentrated phosphoric acid is relatively low, water is easily evaporated and the phosphoric acid becomes concentrated during an etching process. Accordingly, etching rate of silicon nitride decreases because now highly concentrated phosphoric acid does not boil. For this reason, the present inventors suggested that the etching process proceeds in a pressurized state of a reactor.

As a result, it was confirmed that even in the case of using the etching composition including a less concentrated phosphoric acid, etching of a silicon nitride layer is rapidly performed like the etching composition including a highly concentrated phosphoric acid, and also, a damage to a silicon oxide layer may be minimized. Thus, the present disclosure has been suggested.

Hereinafter, the present disclosure will be described in detail.

The etching composition according to an exemplary embodiment may be an etching composition under pressure which may selectively etch a silicon nitride layer against a silicon oxide layer. As described above, the present inventors found that the silicon nitride layer may be etched at a high selectivity by using a phosphoric acid at a high temperature, which is applied to a reactor capable of pressurization so that the phosphoric acid is present as a liquid state even at a temperature higher than a boiling point at atmospheric pressure. Furthermore, according to the present disclosure, even when a phosphoric acid is used in a significantly smaller amount than the amount of the phosphoric acid of a conventional etching composition, a silicon nitride layer may be etched at a high selectivity.

Specifically, the etching composition according to an exemplary embodiment of the present disclosure may be an etching composition under pressure including 85 wt % or less of a phosphoric acid, based on the total weight of the etching composition. In addition, the phosphoric acid may be included at 80 wt % or less, 75 wt % or less, 70 wt % or less, or 30 to 40 wt %.

The etching composition according to the present disclosure may implement excellent etchability to a target object to be etched, only with the simple composition and conditions as described above. However, when only the composition or the conditions (pressurization method) according to the present disclosure is satisfied, the same effect may not be implemented. For example, when only the etching composition according to the present disclosure is satisfied, water is continuously evaporated during the etching process, and thus, the concentration of the phosphoric acid is increased, and the boiling point of the phosphoric acid is raised. In this case, the temperature set for the etching composition is lower than the boiling point of the phosphoric acid after evaporation, and thus, the etching rate of the silicon nitride layer is decreased.

An object to be etched of the etching composition under pressure according to an exemplary embodiment of the present disclosure may be a wafer in which both the silicon oxide layer and the silicon nitride layer are exposed to the surface; a wafer having a multiple stack structure having the silicon oxide layer and the silicon nitride layer as a unit layer; or the like, and may cover all forms deposited in various embodiments. In addition, the unit layer may be a silicon nitride layer deposited on a silicon oxide layer, or a silicon oxide layer deposited on a silicon nitride layer.

In addition, a remainder of the etching composition under pressure according to an exemplary embodiment of the present disclosure is water. Water is not particularly limited, but is specifically distilled water or deionized water (DIW), and more specifically, is deionized water for a semiconductor process and may have a resistivity value of 18 MΩ·cm or more.

The etching composition under pressure according to an exemplary embodiment of the present disclosure may not substantially include the compound containing a silicon atom.

In addition, the etching composition under pressure according to an exemplary embodiment of the present disclosure may be used at 2 to 20 atm. When the pressurization conditions as such are satisfied, a silicon nitride layer is etched without an oxide regrowth issue, and a trade-off problem between an etching rate and an etching selectivity of the silicon nitride layer is solved, thereby improving both, which is thus preferred.

The etching composition under pressure according to an exemplary embodiment of the present disclosure may satisfy the following (A) to (C). Here, the etching properties as follows may be an effect in a single layer:

(A) an etching rate of the silicon nitride layer is 50 Å/min or more,

(B) an etching rate of the silicon oxide layer is 0 to 10 Å/min, and

(C) an etching selectivity of the silicon nitride layer to the silicon oxide layer is 2 to 400.

For example, the etching rate of the silicon nitride layer may satisfy 52 Å/min or more, 55 Å/min or more, or 58 to 100 Å/min.

For example, the etching rate of the silicon oxide layer may satisfy 8 Å/min or less, 7 Å/min or less, or 0.1 to 6.5 Å/min.

For example, the etching selectivity of the silicon nitride layer to the silicon oxide layer may be in a range of 13 or more, 20 or more, 30 or more, 50 or more, or 100 to 300.

In addition, the etching composition under pressure according to an exemplary embodiment of the present disclosure may further satisfy the following (D). Here, the etching properties as follows may be an effect in a vertical stack structure:

(D) a vertical stack structure having the silicon oxide layer and the silicon nitride layer as a unit layer, an outer thickness (Tₒ) to an inner thickness (Tᵢ) of the silicon oxide layer satisfies the following Equation 1:

0.90≤Tₒ/Tᵢ≤1.0 [Equation 1]

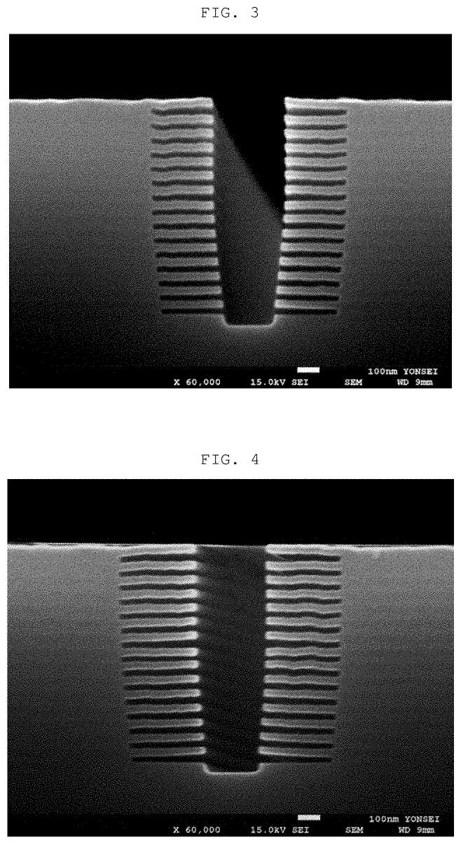

According to the illustration in FIG. 3, specifically, the inner thickness (Tᵢ) of the silicon oxide layer may refer to a thickness of the silicon oxide layer measured at the end in the etch depth direction where the silicon nitride layer is etched, and the outer thickness (Tₒ) of the silicon oxide layer may refer to a thickness of the silicon oxide layer measured at the end in the opposite direction to the Tᵢ.

For example, when Equation 1 (Tₒ/Tᵢ) has a value converging to 1, it means that there is no etching of the silicon oxide layer.

For example, the etching composition under pressure may satisfy the Equation 1 (Tₒ/Tᵢ) of 0.9 to 0.99, or 0.9 to 0.98.

When the etching composition under pressure according to an exemplary embodiment of the present disclosure includes 30 to 80 wt % or 30 to 70 wt % of the phosphoric acid, a more improved etching selectivity may be implemented. Specifically, the etching composition under pressure including 30 to 40 wt % of the phosphoric acid may have an etching selectivity I in a range of 100 or more or 100 to 300.

In addition, the etching composition under pressure according to an exemplary embodiment of the present disclosure may further satisfy the following I. That is, the etching composition under pressure may satisfy all of the etching properties of (A) to I:

I in a vertical stack structure having the silicon oxide layer and the silicon nitride layer as a unit layer, a representative etching selectivity (ER_{Si3N4}/ER_{SiO2.o}) satisfies the following Equation 2. Here, the following Equation 2 may have a resulting value confirmed from the method illustrated in FIG. 6:

ER_{Si3N4}/ER_{SiO2,o}≥75 [Equation 1]

wherein

ER_{Si3N4} is a silicon nitride layer etching rate, and

ER_{SiO2,o} is a silicon oxide layer external etching rate.

The etching composition under pressure according to an exemplary embodiment may provide an advantage in etching properties in a vertical stack structure as well as etching properties in a single layer.

As an example, the etching composition under pressure may satisfy Equation 2 of I of 300 or less or 75 to 250.

In addition, the etching composition under pressure according to an exemplary embodiment of the present disclosure may be prepared by a commonly known method, and is not limited as long as it has a purity for a semiconductor process.

In addition, the present disclosure provides an etching method of selectively etching a silicon nitride layer against a silicon oxide layer using the etching composition under pressure described above, and a method of manufacturing a semiconductor device including the etching method.

The etching method according to an exemplary embodiment of the present disclosure may include, specifically, adding a wafer including the etching composition under pressure according to the present disclosure and an object to be etched to a reactor, and performing etching by pressurizing at 2 to 20 atm and heating the reactor.

The step may be etching at a high temperature by heating to 100° C. or higher in a state of maintaining a pressurized state in a range of 2 to 20 atm. As an example, the step may be performed in a pressurized state in a range of 3 to 15 atm or 5 to 10 atm.

In the etching method according to an exemplary embodiment of the present disclosure, the heating may be performed at a process temperature in a range of 100 to 500° C., 100 to 300° C., 150 to 300° C., or 160 to 200° C., and an appropriate temperature may be changed if necessary, depending on other processes or other factors, of course.

In the etching method according to an exemplary embodiment of the present disclosure, the specific range of the pressurization conditions may be 2 to 5 atm, 2 to 10 atm, 3 to 10 atm, 3 to 20 atm, or 5 to 20 atm. When the pressurization conditions as such are satisfied, synergy may be imparted to etchability in a vertical stack structure. Here, synergy imparted etchability is meaningful in terms of going beyond a level of increase of a simple quantitative effect by applying pressurization conditions.

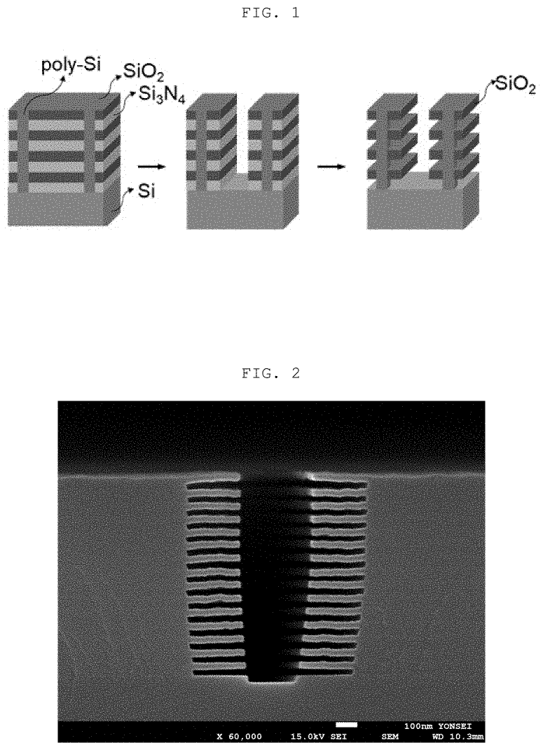

In the etching method according to an exemplary embodiment of the present disclosure, the object to be etched may be a wafer in which both the silicon oxide layer and the silicon nitride layer are exposed to the surface; a wafer having a stacked structure having the silicon oxide layer and the silicon nitride layer as a unit layer; or the like, and may cover all forms deposited in various embodiments. In addition, the unit layer may be a silicon nitride layer deposited on a silicon oxide layer, or a silicon oxide layer deposited on a silicon nitride layer. A specific embodiment of the wafer having a stacked structure having the silicon oxide layer and the silicon nitride layer as a unit layer may be exemplified as a vertical stack structure illustrated in the following FIG. 1.

The silicon nitride layer may include a SiN layer, a SiON layer, a doped SiN layer, and the like, and may mean film quality mainly used as an insulation film in forming a gate electrode and the like, but it is not limited as long as it belongs to the technical field which has the purpose of selectively etching of the silicon nitride layer against the silicon oxide layer.

In addition, the silicon oxide layer is not limited as long as it is a silicon oxide layer commonly used in the art, and as an example, may be at least one or more layers selected from the group consisting of a spin on dielectric (SOD) layer, a high density plasma (HDP) layer, a thermal oxide layer, a borophosphate silicate glass (BPSG) layer, a phosphosilicate glass (PSG) layer, a borosilicate glass (BSG) layer, a polysilazane (PSZ) layer, a fluorinated silicate glass (FSG) layer, a low pressure tetraethyl orthosilicate (LP-TEOS) layer, a plasma enhanced tetraethyl orthosilicate (PETEOS) layer, a high temperature oxide (HTO) layer, a medium temperature oxide (MTO) layer, an undopped silicate glass (USG) layer, a spin on glass (SOG) layer, an advanced planarization layer (APL) layer, an atomic layer deposition (ALD) layer, a plasma enhanced oxide (Pe-oxide) layer, an O₃-tetraethyl orthosilicate (O₃-TEOS) layer, and the like. However, these are only a specific example, and the present disclosure is not limited thereto.

In the etching method according to an exemplary embodiment of the present disclosure, the wafer is not limited as long as it is a common wafer, and for example, may be silicon, quartz, glass, a silicon wafer, a polymer, a metal, a metal oxide, and the like, but is not limited thereto. As an example of a polymer substrate, a film substrate such as polyethylene terephthalate, polycarbonate, polyimide, polyethylene naphthalate, and a cycloolefin polymer may be used, but the present disclosure is not limited thereto.

In addition, the present disclosure provides a method of suppressing abnormal regrowth of a silicon oxide layer using the etching composition under pressure described above. The method may be performed according to a method commonly used in the art, of course.

Hereinafter, the present disclosure will be described in more detail with reference to the examples and the comparative examples. However, the following examples and comparative examples are only one example for describing the present disclosure in more detail, and do not limit the present disclosure in any way. Unless otherwise stated, the unit of temperature is ° C., and unless otherwise stated, the unit of an amount of a composition used is wt %.

### EXAMPLES 1 TO 6 AND COMPARATIVE EXAMPLE 1

Mixing was performed at each composition ratio shown in the following Table 1, and stirring was performed at a room temperature at a speed of 500 rpm for 5 minutes to prepare an etching composition. The content of deionized water was 100 g, as a remainder so that the total weight satisfied 100 wt %. Here, etching in Comparative Example 1 was performed under atmospheric pressure conditions.

Example 1: deionized water+50 wt% of phosphoric acid, 150° C., pressurized (5.3 atm)

Example 2: deionized water+60 wt % of phosphoric acid, 150° C., pressurized (5.3 atm)

Example 3: deionized water+70 wt % of phosphoric acid, 150° C., pressurized (5.3 atm)

Example 4: deionized water+30 wt % of phosphoric acid, 160° C., pressurized (5.5 atm)

Example 5: deionized water+40 wt % of phosphoric acid, 160° C., pressurized (5.5 atm)

Example 6: deionized water+50 wt % of phosphoric acid, 160° C., pressurized (5.5 atm)

Comparative Example 1: deionized water+85 wt % of phosphoric acid, 160° C., atmospheric pressure

### Evaluation Method

### Etching Evaluation \textcircled{1}

In order to evaluate etchability of the etching compositions prepared in the examples and the comparative Example, a silicon nitride layer (Si₃N₄) and a silicon oxide layer (SiO₂) were alternately deposited on a silicon wafer 15 times by a PECVD method, a photolithography process was performed, and patterning was performed by dry etching, thereby a manufacturing a patterned silicon nitride layer/silicon oxide layer (unit layer) 15-layer vertical stack structure (pattern wafer).

In addition, a LPCVD method was used to deposit each of a silicon nitride layer and a silicon oxide layer on a silicon wafer using a LPCVD method to manufacture each of a blanket silicon nitride layer wafer and a blanket silicon oxide layer wafer (blanket wafer).

Each etching composition prepared in the examples was prepared at 100 ml in a PTFE beaker at room temperature (25° C.) Each of the prepared etching compositions and each of the wafers were added to a reactor capable of pressurization, and an etching process was performed at 5 to 5.5 atm at 150 to 160° C. for 3 minutes to 10 minutes. In addition, with the etching composition prepared in the comparative example, the etching process was performed at 160° C. for 15 minutes. After completing each experiment, each wafer was cleaned with deionized water and dried using nitrogen gas.

For evaluation for each 15-layer vertical stack structure dried after the etching process, a field emission scanning electron microscope (FE-SEM, model name: JEOL-7610-Plus, manufacturer: JEOL Ltd.) was used to measure the depth of the silicon nitride layer which was etched in a horizontal direction and the thickness of the remaining silicon oxide layer. For the reference, in the blanket wafer, an ellipsometer (model name: MG-1000, manufacturer: Nano-View) was used to measure the thicknesses of the silicon nitride layer and the silicon oxide layer, and the etching rate was calculated from the difference in the thickness before and after the experiment. In addition, the etching selectivity (ER_{Si3N4}/ER_{SiO2}) of the silicon nitride layer to the silicon oxide layer was calculated from the etching rate value obtained above.

The results are shown in the following Table 1.

In addition, the cross-section of the 15-layer vertical stack structure of each etching example was measured with SEM, and the images are shown in FIGS. 2 to 5.

### Etching Evaluation \textcircled{2}

In addition, a silicon nitride layer etching rate (ER_{Si3N4}) and a silicon oxide layer etching rate (ER_{SiO2}) obtained from the silicon nitride/silicon oxide 15-layer vertical stack structure, and an etching selectivity (ER_{Si3N4}/ER_{SiO2,o}) determined by the ratio were determined by the method of FIG. 6. Specifically, the etching rate (ER_{Si3N4}) of the silicon nitride layer in a horizontal direction in the 15-layer vertical stack structure was determined, and since it is difficult to determine the etching rate of the silicon oxide layer in a horizontal direction, the silicon oxide layer etching rate (ER_{SiO2}) was determined from the change in the thickness of the silicon oxide layer. In particular, since the outer and inner thicknesses of the silicon oxide layer are often different, the silicon oxide layer etching rate in two portions (outer ER_{SiO2,o} and inner ER_{SiO2,i}) were indicated, respectively, and a ratio (Tₒ/Tᵢ) between the outer thickness and the inner thickness was also indicated. A representative etching selectivity of the silicon nitride to silicon oxide layer is represented as a ratio (ER_{Si3N4}/ER_{SiO2,o}) of the etching rate of silicon nitride layer in the horizontal direction to the etching rate of the outer silicon oxide layer.

The results are shown in the following Table 2.

TABLE 1

| Blanket | ER_{Si3N4} | ER_{SiO2} | Etching |
|---|---|---|---|
| wafer | (Å/min) | (Å/min) | selectivity |
| Example 1 | 60 | 2 | 30 |
| Example 2 | 77 | 2.3 | 33 |
| Example 3 | 86 | 1.6 | 53 |
| Example 4 | 58 | 0.2 | 290 |
| Example 5 | 74 | 0.7 | 106 |
| Example 6 | 80 | 6.2 | 13 |
| Comparative | 72 | 21 | 3.4 |
| Example 1 | | | |

As shown in Table 1, the etching compositions under pressure according to the present disclosure were able to implement the etching rate of the silicon nitride layer at 58 Å/min or more. In particular, when the etching composition under pressure according to the present disclosure was used, an improved etching rate of the silicon nitride layer and a high etching selectivity of the silicon nitride layer to the silicon oxide layer were able to be implemented, even with the use of a low-concentration phosphoric acid. Specifically, in Examples 1 and 4 of the present disclosure, the etching rates of the silicon nitride layer were decreased by 17 to 19% as compared with Comparative Example 1, but the etching selectivities were increased by 9 to 85 times. In addition, in Examples 2 and 5, the etching rates of the silicon nitride layer were increased by 3 to 7% as compared with Comparative Example 1, and the etching selectivities were increased by 10 to 31 times. In addition, in Examples 3 and 6 of the present disclosure, the etching rates of the silicon nitride layer were decreased by 19% and 11% as compared with Comparative Example 1, but the etching selectivities were increased by 16 and 4 times. That is, in Examples 1 to 4, the etching selectivity was greatly increased, and in Examples 2, 3, 5, and 6, both the etching rate and the etching selectivity of the silicon nitride layer were increased, and thus, the etching properties were significantly improved. However, it was confirmed in Comparative Example 1 that the silicon oxide layer was also etched at a high rate, and thus, no advantage in the etching selectivity was provided.

TABLE 2

| | | Outer etching | Inner etching | Ratio of outer | Representative |
|---|---|---|---|---|---|
| | Silicon nitride | rate of silicon | rate of silicon | thickness/inner | etching |
| | layer etching | oxide layer | oxide layer | thickness of | selectivity |
| Pattern | rate (ER_{Si3N4}, | (ER_{SiO2, o}, | (ER_{SiO2, i}, | silicon oxide | ER_{Si3N4}/ |
| wafer | Å/min) | Å/min) | Å/min) | layer (Tₒ/Tᵢ) | ER_{SiO2, o}) |
| Example 4 | 261 | 3.5 | 1.8 | 0.90 | 75 |
| Example 5 | 561 | 3.5 | 1 | 0.94 | 160 |
| Example 6 | 1116 | 7.2 | 4.3 | 0.95 | 155 |
| Comparative | 252 | 5.4 | 1.8 | 0.80 | 48 |
| Example 1 | | | | | |

As shown in Table 2, it was confirmed that the etching composition under pressure according to the present disclosure may implement more pronounced etching properties even in a pattern wafer, that is, a vertical stack structure. Specifically, according to the present disclosure, the etching rate of the silicon nitride layer was improved to 561 and 1116 Å/min, and also, the representative etching selectivity was improved to 160 and 155, in Examples 5 and 6 using a low concentration of a phosphoric acid (40 and 50 wt %), as compared with Comparative Example 1 using 85 wt% of a phosphoric acid. In addition, in Example 4 using a low-concentration phosphoric acid of 30 wt %, the silicon nitride layer etching rate similar to that of Comparative Example 1 using 85 wt % of a phosphoric acid was provided, and the representative etching selectivity improved by about 156% was implemented.

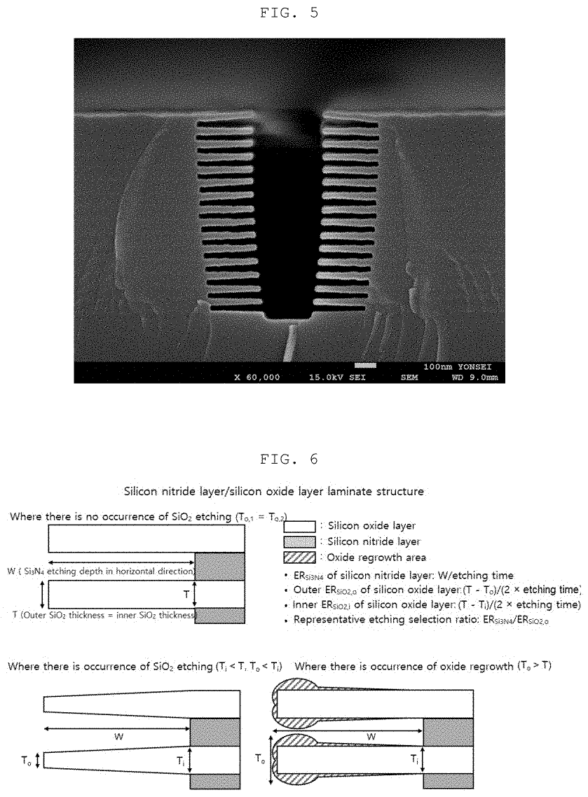

In addition, as shown in Table 2 and FIG. 5, in Comparative Example 1, the silicon oxide layer outer/inner thickness ratio (Tₒ/Tᵢ) was 0.80, the etching selectivity of the silicon nitride layer to the silicon oxide layer was 48, and a thinning phenomenon in which the thickness of the silicon oxide layer was unevenly thinned was observed.

Meanwhile, upon comparison of the ratio (Tₒ/Tᵢ) between the inner thickness and the outer thickness of the etched silicon oxide layer, as shown in Table 2 and FIG. 2, it was confirmed that the etching composition under pressure according to the present disclosure (Example 4) had the ratio (Tₒ/Tᵢ) between the inner thickness and the outer thickness of the silicon oxide layer in the vertical stack structure of 0.9. In addition, as shown in Table 2 and FIG. 3, it was confirmed that the etching composition under pressure according to the present disclosure (Example 5) had the ratio (Tₒ/Tᵢ) between the inner thickness and the outer thickness of the silicon oxide layer in the vertical stack structure of 0.94. In addition, as shown in Table 2 and FIG. 4, it was confirmed that the etching composition under pressure according to the present disclosure (Example 6) had the ratio (Tₒ/Tᵢ) between the inner thickness and the outer thickness of the silicon oxide layer in the vertical stack structure of 0.95.

In particular, in Examples 4 to 6, both the silicon nitride layer etching rate and the etching selectivity were increased, as compared with Comparative Example 1 using 85 wt % of a phosphoric acid, thereby solving the above-mentioned trade-off problem thereby improving both etching rate of silicon nitride and etching selectivity of silicon nitride to silicon oxide. From the numerical values, it is recognized that when the etching process is performed using the etching composition under pressure according to the present disclosure, the etching rate of the silicon nitride layer in the vertical stack structure was improved and occurrence of thinning of the silicon oxide layer was significantly decreased.

From the results, it is recognized that the etching composition under pressure according to the present disclosure may selectively etch the silicon nitride layer very stably even with the use of a low-concentration phosphoric acid. In addition, the present disclosure is distinguished from the conventional technology, in that it was confirmed that significantly improved etchability may be implemented by a pressurization process, and also the object to be etched is changed depending on whether the pressurization process was performed, even with the etching composition having the same composition. In addition, according to the present disclosure, even in the etching process in the vertical stack structure, film quality damage of the silicon oxide layer may be minimized, and occurrence of abnormal oxide regrowth may be prevented, and thus, stability and reliability of the process may be secured.

Accordingly, the etching composition under pressure according to the present disclosure allows selective etching of the silicon nitride layer while preventing deterioration of electrical properties resulting from the overetching of the silicon oxide layer, degradation of the silicon oxide film quality, and occurrence of abnormal oxide regrowth, thereby improving the properties of the semiconductor device.

The etching composition according to the present disclosure includes a low-concentration phosphoric acid as compared with a highly concentrated conventional etching composition, but may effectively suppress etching of a silicon oxide layer, and may implement a high etching selectivity of a silicon nitride layer to a silicon oxide layer. In particular, the etching composition according to the present disclosure may exhibit effective etchability even in a V-NAND structure, and thus, may substantially prevent thinning of a silicon oxide layer.

In addition, the etching composition according to the present disclosure does not use a compound containing a silicon atom, and thus, a possibility of regrowth of an silicon oxide layer during the etching process is significantly decreased.

The etching composition according to the present disclosure suppresses thinning of a silicon oxide layer during an etching process, prevents regrowth of a silicon oxide layer due to a side reaction caused by an additive, and rapidly etches a silicon nitride layer, thereby preventing deterioration of the properties of a semiconductor device to provide a highly reliable semiconductor device.

The etching composition according to the present disclosure may solve a trade-off relation problem between an etching rate and an etching selectivity, and thus, may reduce semiconductor production costs and significantly improve productivity. In addition, use of a low-concentration phosphoric acid may act as a very beneficial commercial advantage.

As described above, as a semiconductor integration is improved, selective etching in a micropattern structure is becoming important in the recent trend, and thus, the etching composition according to the present disclosure may provide beneficial advantages from more diverse perspectives than a conventional etching process.

It will be apparent to those skilled in the art to which the present disclosure pertains that the present disclosure is not limited to the above-described exemplary embodiment, and may be variously substituted, modified, and altered without departing from the scope and spirit of the present disclosure.

What is claimed is:

1. An etching method comprising: selectively etching a silicon nitride layer against a silicon oxide layer, under pressurization conditions, using an etching composition including 85 wt % or less of a phosphoric acid based on a total weight of the etching composition.

2. The etching method of claim 1, wherein the pressurization conditions are 2 to 20 atm.

3. The etching method of claim 1, wherein the following (A) to (C) are satisfied:
(A) an etching rate of the silicon nitride layer is 50 Å/min or more,
(B) an etching rate of the silicon oxide layer is 0 to 10 Å/min, and
(C) an etching selectivity of the silicon nitride layer to the silicon oxide layer is 2 to 400.

4. The etching method of claim 3, wherein the following (D) is satisfied:
(D) in a vertical stack structure having the silicon oxide layer and the silicon nitride layer as a unit layer, an outer thickness (Tₒ) to an inner thickness (Tᵢ) of the silicon oxide layer satisfies the following Equation 1:
0.90≤Tₒ/Tᵢ≤1.0 [Equation 1]

5. The etching method of claim 1, wherein the etching composition includes 30 to 70 wt % of the phosphoric acid.

6. The etching method of claim 5, wherein the etching composition has an etching selectivity of 10 to 400.

7. The etching method of claim 1, wherein the etching composition does not include a compound containing a silicon atom.

8. The etching method of claim 1, wherein an object to be etched of the etching composition is a wafer in which both silicon nitride layer and silicon oxide layer are exposed to a surface or a wafer having a stack structure having the silicon nitride layer and the silicon oxide layer as a unit layer.

9. The etching method of claim 1, wherein the etching method is performed at a high temperature of 100° C. or higher.

10. A method of manufacturing a semiconductor device using the etching method of claim 1.

11. An etching composition under pressure, for selectively etching a silicon nitride layer against a silicon oxide layer, comprising: 85 wt % or less of a phosphoric acid, based on a total weight of the etching composition.
